(19) United States
(12) Patent Application Publication
(10) Pub. No.: US 2026/0334293 A1
(43) Pub. Date: Oct. 22, 2026

(54) EDGE PROTECTION FOR STACKED SEMICONDUCTOR SYSTEMS

(71) Applicant: Micron Technology, Inc., Boise, ID (US)

(72) Inventors: Wei Zhou, Boise, ID (US); Kunal R. Parekh, Boise, ID (US)

(21) Appl. No.: 19/468,455

(22) Filed: Feb. 3, 2026

Related U.S. Application Data
(60) Provisional application No. 63/757,625, filed on Feb. 12, 2025.

(51) Int. Cl. H10W 74/10; H10W 74/01; H10W 74/15; H10W 90/00; H10W 90/20

(52) U.S. Cl. CPC H10W 74/121; H10W 74/012; H10W 74/014; H10W 74/15; H10W 90/291; H10W 90/722

(57) ABSTRACT

Methods, systems, and devices for edge protection for stacked semiconductor systems are described. A system may be fabricated to include a first semiconductor component with one or more first semiconductor dies associated with first circuitry. The system may include a second semiconductor component bonded with the first semiconductor component and including one or more second semiconductor dies associated with second circuitry. The second circuitry may be electrically coupled with the first circuitry. Various molding materials may be formed around the first semiconductor component and the second semiconductor component along one or more respective sidewalls surfaces of the first semiconductor component and the second semiconductor component. Alternatively, a same molding material may be formed around the first semiconductor component and the second semiconductor component. The sidewall surfaces of respective molding materials may be indicative of a separation from other portions of molding materials.

### CROSS REFERENCE

The present Application for Patent claims priority to U.S. Patent Application No. 63/757,625 by Zhou et al., entitled “EDGE PROTECTION FOR STACKED SEMICONDUCTOR SYSTEMS,” filed Feb. 12, 2025, which is assigned to the assignee hereof, and which is expressly incorporated by reference in its entirety herein.

### TECHNICAL FIELD

The following relates to one or more semiconductor systems, including edge protection for stacked semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports edge protection for stacked semiconductor systems in accordance with examples as disclosed herein.

FIG. 2 shows an example of a system that supports edge protection for stacked semiconductor systems in accordance with examples as disclosed herein.

FIG. 3 shows an example of a semiconductor system in accordance with examples as disclosed herein.

FIGS. 4A through 4D illustrate examples of fabrication operations that support formation of a semiconductor system that supports edge protection for stacked semiconductor systems in accordance with examples as disclosed herein.

FIGS. 5A through 5D illustrate examples of fabrication operations that support formation of a semiconductor system that supports edge protection for stacked semiconductor systems in accordance with examples as disclosed herein.

FIGS. 6 and 7 show flowcharts illustrating a method or methods that support edge protection for stacked semiconductor systems in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a tightly-coupled dynamic random access memory (TCDRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a TCDRAM system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some techniques for fabricating a semiconductor system may include bonding one or more first semiconductor components (e.g., semiconductor dies, memory dies, memory array dies, a stack of memory dies) with respective second semiconductor components (e.g., semiconductor dies, logic dies, interface dies) of a same wafer (e.g., via stack-to-wafer bonding). After the first semiconductor components are bonded with the wafer, the first semiconductor components and the exposed surface of the wafer and may be covered (e.g., coated) with a molding material (e.g., a mold compound, an epoxy material). The wafer may be divided to separate (e.g., singulate) respective bonded sets of components (e.g., a set of memory dies stacked over a logic die), and the molding material may protect the sidewalls of the first semiconductor components. However, these singulation operations may expose one or more surfaces (e.g., sidewall surfaces) of the second semiconductor components, which may be susceptible to damage during subsequent fabrication operations and handling. Moreover, based on the stack-to-wafer bonding operation, the components of the wafer may not be individually validated prior to bonding with the first components. As such, a faulty component (e.g., a faulty logic die) may be bonded with one or more operational components (e.g., validated components, operational memory dies). Thus, some fabrication techniques may result in various system defects (e.g., based on damage to die edges, based on bonding prior to singulation), which may decrease a manufacturing yield, increase waste, and increase fabrication cost of semiconductor systems.

In accordance with one or more techniques described herein, a wafer of second semiconductor components (e.g., interface dies) may be singulated (e.g., separated, cut) and individually validated prior to bonding with one or more other semiconductor components (e.g., DRAM dies, DRAM cubes). After validation, the second semiconductor components (e.g., the known-good-dies (KGDs)) may be bonded with a carrier material, and one or more first semiconductor components (e.g., dynamic random access memory (DRAM) dies) may be stacked over (e.g., and bonded with) the second components. In some examples, the first semiconductor components may be sequentially stacked over a second component (e.g., one-by-one). In some other examples, multiple first semiconductor components may be bonded together (e.g., as a DRAM cube) prior to bonding with other components. After bonding, a molding material may be formed to encapsulate (e.g., protect, surround, cover, shield) the sidewall surfaces (e.g., edges, exposed surfaces) of the second semiconductor components (e.g., and the edges of the first semiconductor components). The bonded components may thus be singulated without exposing the sidewall surfaces of the semiconductor components (e.g., the interface dies). Thus, the one or more techniques herein may enable increased yield (e.g., based on the protective molding material and bonding of KGDs), reduced waste, and improved efficiency during fabrication of semiconductor systems.

In addition to applicability in memory systems as described herein, techniques for edge protection for stacked semiconductor systems may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and reducing a quantity of rejected devices, which may result in lowered production emissions and reduce electronic waste, among other benefits.

Features of the disclosure are illustrated and described in the context of systems and architectures. Features of the disclosure are further illustrated and described in the context of devices, operations, and flowcharts.

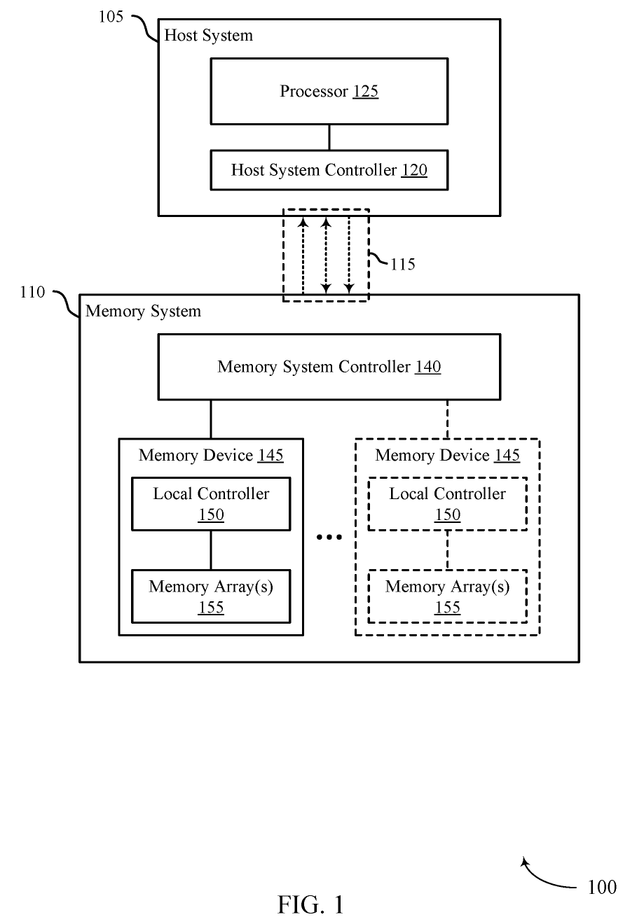

FIG. 1 shows an example of a system 100 that supports edge protection for stacked semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a TCDRAM system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

Some techniques for fabricating a system 100 or portion thereof may include bonding one or more first semiconductor components (e.g., of a memory system 110 or portion thereof, of a memory device 145 or a portion thereof) with respective second semiconductor components (e.g., logic dies, interface dies, of a host system 105 or a portion thereof, of a memory system 110, or portion thereof) of a same wafer (e.g., via stack-to-wafer bonding). After the first semiconductor components are bonded with the wafer, the wafer may be divided to singulate each bonded set of dies. However, these singulation operations may expose edges of the second semiconductor components, which may be susceptible to damage during subsequent fabrication operations and handling. Moreover, based on the stack-to-wafer bonding operation, the components of the wafer may not be individually validated prior to bonding with the first components. As such, a faulty component (e.g., logic die, of a host system 105 or portion thereof, of a memory system 110 or portion thereof) may be bonded with one or more operational components (e.g., memory dies). Thus, some fabrication techniques may result in various system defects (e.g., based on damage to die edges, based on bonding prior to singulation), which may decrease a manufacturing yield, increase waste, and increase fabrication cost of systems 100 or portions thereof.

In accordance with one or more techniques described herein, a wafer of second semiconductor components (e.g., interface dies) may be singulated (e.g., separated, cut) and individually validated prior to bonding with one or more other semiconductor components (e.g., DRAM dies, DRAM cubes). After validation, the second semiconductor components (e.g., KGDs) may be bonded with a carrier material, and one or more first semiconductor components (e.g., KGDs) may be bonded with the second components. After bonding, a molding material may be formed to encapsulate the sidewall surfaces (e.g., edges, exposed surfaces) the second semiconductor components and the first semiconductor components. The sidewall surfaces of the bonded components of a system 100 may thus be protected during manufacture. As such, the one or more techniques herein may result in increased yield (e.g., based on the protective molding material and bonding of KGDs), reduced waste, and improved efficiency during fabrication of a system 100.

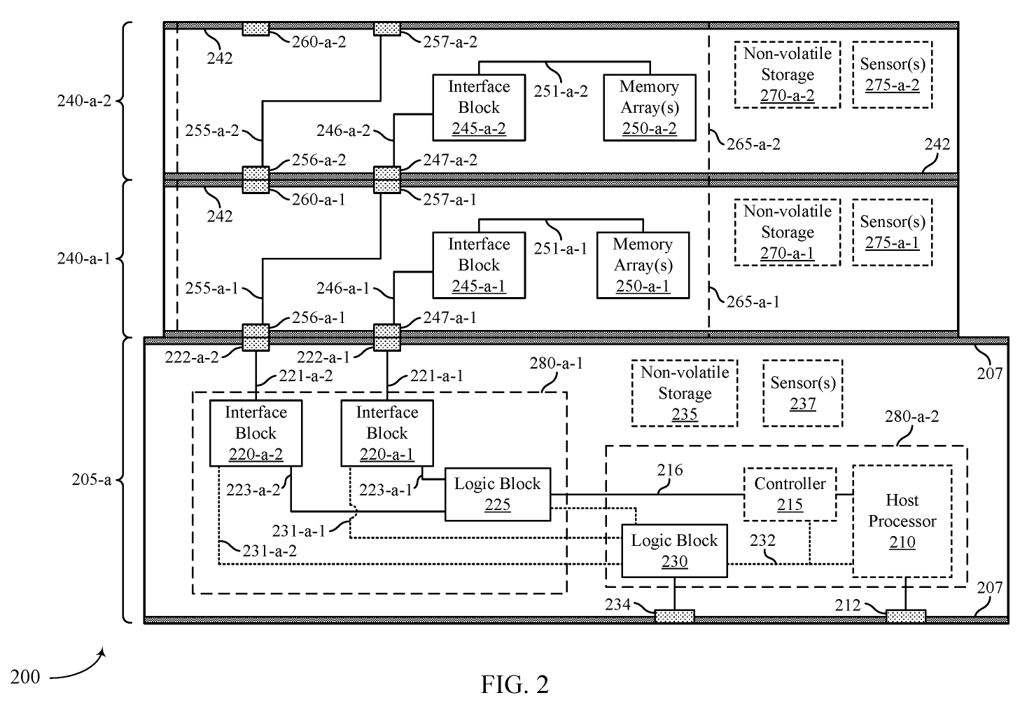

FIG. 2 shows an example of a system 200 (e.g., a semiconductor system, a system of coupled semiconductor dies, an HBM system, a TCDRAM system) that supports edge protection for stacked semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples.

Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., TCDRAM implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a TCDRAM implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a tightly-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some techniques for fabricating a system 200 may include bonding one or more dies 240 with respective dies 205 of a same wafer (e.g., via stack-to-wafer bonding, before singulating dies 205 from the wafer). After the dies 240 are bonded with the wafer of dies 205, the wafer may be divided to singulate each bonded set of dies (e.g., to singulate respective systems 200). However, these singulation operations may expose one or more sidewalls of dies 205, which may cause the dies 205 to be susceptible to damage during subsequent fabrication operations and handling. Moreover, based on the stack-to-wafer bonding operation, the dies 205 may not be individually validated prior to bonding with dies 240. As such, a faulty die 205 may be bonded with one or more operational dies 240. Thus, some fabrication techniques may result in various defects, which may decrease a manufacturing yield, increase waste, and increase fabrication cost of systems 200.

In accordance with one or more techniques described herein, a wafer of dies 205 (e.g., interface dies) may be singulated (e.g., separated, cut) and dies 205 may be individually validated (e.g., confirmed to satisfy one or more evaluation operations) prior to bonding with one or more other dies (e.g., dies 240). After validation, the dies 205 (e.g., KGDs) may be bonded with a carrier material, and one or more dies 240 (e.g., KGDs) may be bonded with the dies 205. After bonding, a molding material may be formed to encapsulate (e.g., protect, cover, shield) the sidewall surfaces (e.g., edges) of the dies 205 and the dies 240. The sidewall surfaces of the bonded components of systems 200 may thus be protected during manufacture. As such, the one or more techniques herein may be associated with increased yield, reduced waste, and improved efficiency during fabrication of systems 200.

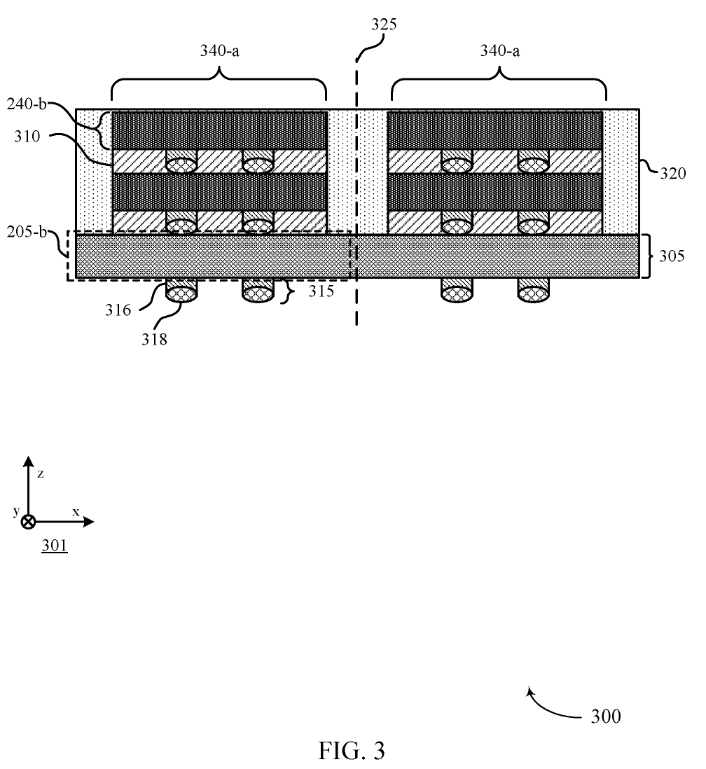

FIG. 3 shows an example of a system 300 in accordance with examples as disclosed herein. The system 300 (e.g., a semiconductor system) may be an example of or include one or more aspects of a system 100 or a system 200, and may be described with reference to an x direction, a y-direction, and a z-direction of a coordinate system 301. The system 300 may include one or more stacks of components. For instance, each stack may include a component 340 (e.g., a semiconductor component, a semiconductor die or stack of dies, a component 340-a, a DRAM cube, a DRAM stack), which may include one or more dies 240-b (e.g., memory array dies, core dies, DRAM dies), and a component 305 (e.g., a semiconductor component, a semiconductor wafer or stack of wafers, an interface wafer, an interface component, a logic component), which may include a set of multiple dies 205-b (e.g., interface dies, logic dies, dies before singulation). Although a system 300 may implement dies 205-b and dies 240-b, the described techniques may be implemented in accordance with other types of semiconductor components or combinations thereof.

A die 205-b may include one or more contacts 315 (e.g., conductive contacts, contacts 222, front side contacts), which may be formed of one or more conductive materials. For example, a first portion 316 (e.g., a pillar) of a contact 315 may include a first conductive material (e.g., copper) and a second portion 318 of the contact 315 may include a second conductive material (e.g., solder, aluminum). In some examples, contacts 315 may support a solder bond with other components. In some other examples, contacts 315 may support one or more hybrid bonding techniques (e.g., a simultaneous bonding of dielectric and conductive material). A die 205-b may also include one or more other conductive contacts (e.g., back side contacts, not shown) to support bonding with a component 340-a. In some examples, each die 240-b may include a respective set of one or more contacts 315 (e.g., contacts 256, contacts 247, front side contacts), and one or more other conductive contacts (e.g., back side contacts, not shown) to support bonding (e.g., solder bonding, hybrid bonding) with other dies 240-b. In some cases, a molding material 310 (e.g., a DRAM die to DRAM die molded underfill (MUF) or non-conductive fill (NCF)) may be formed between dies 240-b (e.g., for mechanical stability or electrical isolation). Although, FIG. 3 illustrates examples quantities of components 340, components 305, dies 240-b, dies 205-c, contacts 315, and other features, the techniques described herein may be applicable for various configurations of such aspects, including greater quantities than shown or fewer quantities than shown.

In some fabrication techniques (e.g., in HBM stacking methods), a component 305 may be bonded to a carrier material (e.g., a silicon carrier, using an adhesive material or glue) and may undergo one or more back side operations to prepare for bonding with components 340-a. The components 340-a may be stacked over the component 305 (e.g., bonded with the backside of respective dies 205-b of the component 305), and a molding material 320 (e.g., an epoxy material, a package MUF) may be formed over the components 340-a and the component 305. The carrier material (e.g., and the adhesive) may then be removed, which may expose the contacts 315 of the dies 205-b. In some cases, the bonded component stacks (e.g., a bonded set of a component 340-a and a die 205-a) may be singulated (e.g., cut, divided, separated) along a boundary 325 to separate individual systems (e.g., as an assembled product).

In some examples, singulation operations may expose one or more surfaces of the component 305 (e.g., sidewall surfaces of the singulated wafer, singulation surfaces). For example, although sidewall surfaces (e.g., component edges, lateral boundaries along the x-direction, y-direction, or both) of the components 340-a may be protected by the molding material 320 after singulation, sidewall surfaces of the component 305 (e.g., of the dies 205-b) may be exposed after singulation and may be susceptible to damage during subsequent fabrication operations and handling. Such damage may cause the bonded system to be rejected and discarded. Moreover, the individual dies 205-b of the component 305 may not be validated prior to bonding with the dies 240-b. As such, a faulty die 205-b may be bonded with one or more operational dies 240-b, which may decrease yield and increase waste.

In accordance with techniques described herein, dies 205-b may be singulated from a component 305 and validated prior to bonding with other components. Accordingly, the dies 205-b may be confirmed as operational (e.g., as KGDs) and additional molding material may be formed around the edges of a die 205-b to protect them from damage. Thus, by applying the one or more techniques herein, systems 300 may be fabricated with increased yield (e.g., based on the protective molding material and bonding of KGDs), reduced waste, and improved efficiency overall.

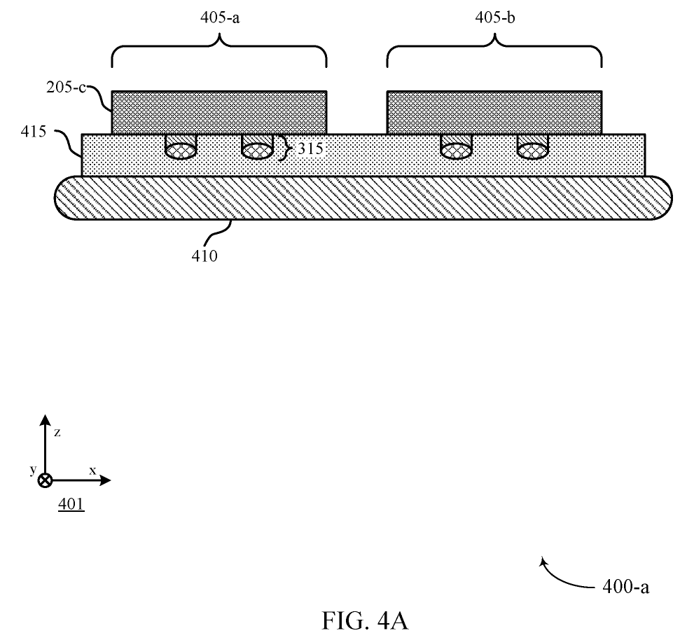

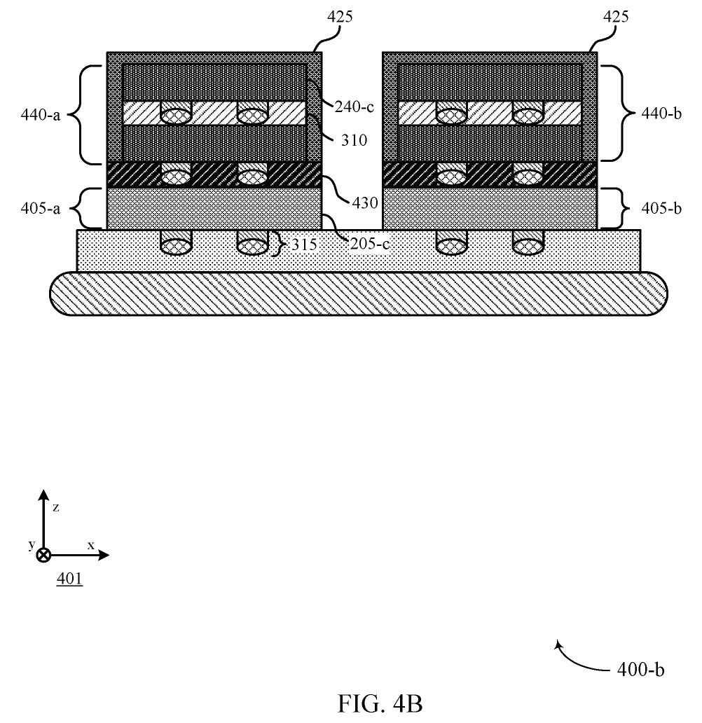

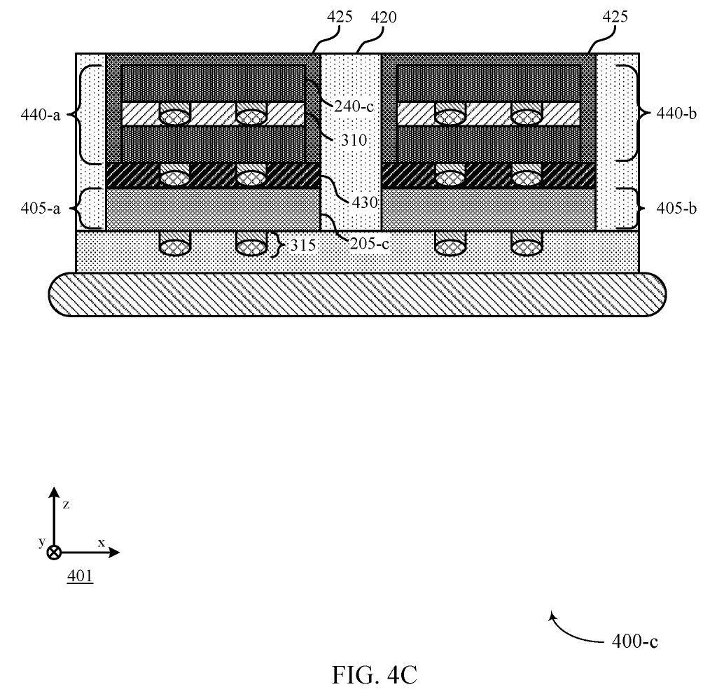

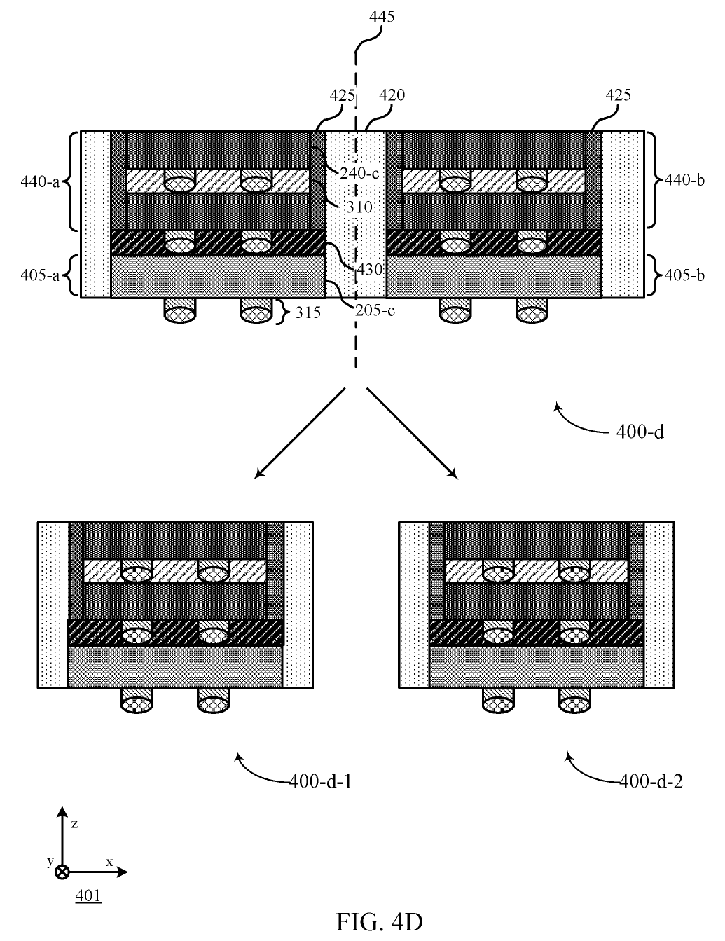

FIGS. 4A - 4D illustrate examples of operations that support edge protection for stacked semiconductor systems in accordance with examples as disclosed herein. Operations are illustrated with reference to a system 400 (e.g., a semiconductor system, a semiconductor stack, a semiconductor device, a semiconductor subcomponent), which may be an example of or include an electronic device (e.g., a system 100, a memory system 110, a host system 105, a system 200, a system 300), or a portion thereof. For example, FIGS. 4A - 4D may illustrate aspects of a first sequence of operations that support manufacturing a system 100 or a portion thereof, a system 200 or a portion thereof, or some other device.

Each of FIGS. 4A - 4D may illustrate aspects of the system 400 after different subsets of the fabrication operations for forming the system 400 (e.g., illustrated as a system 400‑a after a first set of one or more fabrication operations, as a system 400‑b after a second set of one or more fabrication operations, and so on). Each view of FIGS. 4A - 4D may be described with reference to an x-direction, a y-direction, and a z-direction of a coordinate system 401. For example, aspects of the system 400 may be illustrated in accordance with a cut plane (e.g., along an xz-plane) to show embedded features of the system 400. Although, FIGS. 4A - 4D illustrate examples quantities of various features and example dimensionality, the techniques described herein may be applicable for various configurations of such aspects, including greater quantities than shown, fewer quantities than shown, and different dimensionality than shown.

Operations illustrated in and described with reference to FIGS. 4A - 4D may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the system 400. In some examples, operations performed by such a manufacturing system may be supported by a process controller or its components as described herein (e.g., including instructions stored in a non-transitory computer-readable medium that are executable by a processing system to cause the manufacturing system to perform the operations).

In some examples, portions of the system 400 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, solder, some other conductive material, or any combination thereof.

FIG. 4A shows an example of a cross-sectional view of a system 400-a after a first set of one or more fabrication operations. For example, the first operations may include bonding components 405 (e.g., semiconductor components, components singulated from a component 305, components 405-a and 405-b) with a carrier 410 (e.g., before bonding the component(s) 405 with other components). Each component 405 may include a die 205-c associated with respective circuitry (not shown) and one or more contacts 315 (e.g., copper pillars, solder contacts) coupled with the circuitry of the die 205-c. In some examples, a bond between a component 405 and the carrier 410 may be based on a material 415 (e.g., an adhesive material, a temporary bonding film (TBF), an epoxy used for adhesive properties) and the contacts 315 may be embedded in (e.g., extend into) the material 415.

In some examples, contacts 315 may be formed using a “pillar-first” technique in which the contacts 315 are formed prior to bonding with other components (e.g., the carrier 410, prior to mounting to the material 415). In some other examples, contacts 315 may be formed using a “pillar-last” technique in which the contacts 315 are formed after bonding with other components (e.g., the carrier 410, after mounting to the material 415, after removing from the carrier 410). In some examples, the first operations may include determining that each component 405 satisfies one or more evaluation operations (e.g., qualifies as a KGD), and bonding the component 405 with the carrier 410 may be based on such a determination (e.g., based on satisfying one or more evaluation operations).

FIG. 4B shows an example of a cross-sectional view of a system 400-b after a second set of one or more fabrication operations. For example, the second operations may include bonding (e.g., a front side of) a component 440 (e.g., a semiconductor component, a pre-assembled DRAM cube, components 440-a and 440-b) with (e.g., a back side of) each of the components 405. Each component 440 may include one or more dies (e.g., dies 240-c, a single die 240-c, multiple dies 240-c bonded in a stack) associated with circuitry (e.g., first circuitry, not shown). In some examples, the second operations may include bonding a front side of a die 240-c (e.g., the contacts 315) of a component 440 with a back side of a die 205-c of the component 405 (e.g., via solder bonding or hybrid bonding). In some examples, the circuitry of the components 440 may be coupled with the circuitry of the components 405 based on the bonding (e.g., via contacts 315 of the component 440). In some examples, bonding (e.g., stacking) of components 440 and bonding components 440 with components 405 may be performed by separate entities (e.g., by separate fabrication facilities, by different manufacturers).

In some examples, each component 440 may include the molding material 310 (e.g., a DRAM stack MUF) between one or more pairs of the dies 240-c. The molding material 310 may be in contact with a molding material 425 (e.g., an epoxy material, a mold compound, an epoxy molding compound (EMC)). In some examples, the molding material 425 may be formed (e.g., separate from or prior to the second operations) around the component 440 along one or more sidewall surfaces (e.g., edges, lateral boundaries along the x-direction) of the component 440. In some examples, the second operations may include forming a molding material 430 (e.g., a DRAM stack to interface die MUF or NCF) between the component 440 and the component 405 (e.g., as part of or after bonding). The molding material 430 may be in contact with a surface (e.g., a back side) of the component 405, a surface (e.g., a front side) of the component 440, and the molding material 425.

Although each of the components 405 is shown as being bonded with a single component 440, in some other examples, a component 405 may be bonded with any quantity of multiple components 440 (e.g., multiple sets of one or more dies bonded with a same component 405). For example, additional components 440 may be stacked on the component 440-a and the component 440-b, or adjacent to the components 440-a and the component 440-b, or both. In some examples, the second operations may include bonding one or more additional components 440 (not shown) with the component 440-a and thus with the component 405-a. In some examples, circuitry of an additional component 440 may be coupled with circuitry of the component 405-a (e.g., and with the circuitry of the component 440-a) based on the bonding. Each additional component 440 may be associated with (e.g., adjacent to, enclosed by) a respective portion of molding material 425.

In some examples, forming the system 400-b may include forming multiple stacks at a time (e.g., including any quantity of stacks). For example, the second operations may include bonding the component 440-a with the component 405-a and bonding a component 440-b with a component 405-b. The component 440-b may include one or more dies 240-c associated with respective circuitry (e.g., third circuitry) and may include a second portion the molding material 425 around the component 440-b along one or more sidewall surfaces of the component 440-b. The component 405-b may also include one or more dies 205-c associated with respective circuitry (e.g., fourth circuitry, and the circuitry of the component 440-b may be coupled with the circuitry of the component 405-b based on the bonding. In some examples, each of the dies 240-c may include a respective set of one or more memory arrays and the dies 205-c (e.g., the second circuitry) may include interface circuitry operable to access the respective sets of one or more memory arrays.

FIG. 4C shows an example of a cross-sectional view of a system 400-c after a third set of one or more fabrication operations. For example, the third operations may include forming, after bonding the component 440 with the component 405, a molding material 420 (e.g., an epoxy material, a mold compound material, an EMC material, a package MUF, the molding material 320) around each component 440, along one or more sidewall surfaces of the component 405 (e.g., lateral boundaries of the component 405 along the x-direction, along the y-direction, or both), and around the molding material 425 (e.g., along one or more sidewall surfaces of the molding material 425). In some examples, the molding material 420 may be formed after bonding multiple components 440 (not shown) with a component 405, in which case the molding material 420 may be formed around a first portion of the molding material (e.g., associated with a first component 440) and a second portion of the molding material 425 (e.g., associated with a second component 440) along one or more sidewall surfaces of each portion. In some examples, the molding material 420 may be formed after bonding other stacks together (e.g., after bonding the component 440-a with the component 405-a and bonding the component 440-b and the component 405-b). For example, the molding material 420 may be formed around each component 405 along the sidewall surfaces of the component 405 and around each portion of the molding material 425 along one or more sidewall surfaces of the molding materials 425. Accordingly, the sidewall surfaces of the dies 205-c may be protected by the molding material 420 (e.g., after singulation), which may increase manufacturing yield.

FIG. 4D shows an example of a cross-sectional view of a system 400-d after a fourth set of one or more fabrication operations. For example, the fourth operations may include exposing contacts 315 at surface (e.g., the front side) of the components 405 opposite from a surface (e.g., the back side) of the components 405 bonded with the components 440, which may be based on separating the components 405 from the carrier 410 (e.g., after bonding components 440 with the components 405, as an assembly that is held together by molding material 420). In some examples, the contacts 315 may be coupled with the circuitry of the die 205-c. In some examples, the fourth operations may include separating the bonded component 440-a and component 405-a (e.g., forming a system 400-d-1) from the bonded component 440-b and component 405-b (e.g., forming a system 400-d-2) based on a separation through the molding material 420 (e.g., along a boundary 445, along a separation plane).

Thus, a system 400 (e.g., a system 400-d-1, a system 400-d-2) may be fabricated to include one or more components 440, each of which may include one or more semiconductor dies (e.g., dies 240) associated with first circuitry. In some examples, the one or more dies may include multiple dies bonded in a stack. The system 400 may include one or more components 405 bonded with the one or more components 440. The component(s) 405 may include one or more semiconductor dies (e.g., a die 205) associated with second circuitry. The second circuitry may be electrically coupled with the first circuitry via one or more conductive paths (e.g., via respective contacts 315 of each component) between the component 405 and the component(s) 440. In some examples, each of the dies of a component 440 may include a respective set of one or more memory arrays of multiple memory arrays and the one or more dies of the component 405 may include interface circuitry operable to access the memory arrays.

A system 400 may include a molding material 425 around (e.g., around in an xy-plane) the component(s) 440 along one or more sidewall surfaces (e.g., surfaces in xz-planes, surfaces in yz-planes) of the component(s) 440, and the one or more sidewall surfaces of the component(s) 440 may extend (e.g., along the z-direction) from a bonding surface of the component(s) 440 (e.g., a surface bonded with the component 405). In some examples, the system 400 may also include a molding material 420 around the component(s) 405 along one or more sidewall surfaces of the component(s) 405, and around the molding material 425 along one or more sidewall surfaces of the molding material 425. The one or more sidewall surfaces of the component(s) 405 may extend (e.g., along the z-direction) from a bonding

surface of the component 405 (e.g., a surface bonded with the component 440). In some examples, the system 400 may further include a molding material 310 between one or more pairs of the dies 240-c, and the molding material 310 may be in contact with the molding material 425. In some examples, the system 400 may include a molding material 430 between the component 440 and the component 405, and the molding material 430 may be in contact with a surface of the component 440, a surface of the component 405, the molding material 425, and the molding material 420.

A system 400 may include one or more contacts 315 at a surface (e.g., a front side) of a component 405 opposite from a surface (e.g., a front side) of the component 405 bonded with the component 440. In some examples, contacts 315 may be coupled with the circuitry of the component 440. In some examples, one or more sidewall surfaces of the molding material 420 (e.g., of the system 400-d-1 and the system 400-d-2) may be indicative of a separation (e.g., based on a disfiguration, or on indications of melting, grinding, cutting, or other separation methods) from one or more other portions of the molding material 420. In some examples, the system 400 may include multiple stacks of components (e.g., the system 400 may not be separated into a system 400-d-1 and a system 400-d-2, or multiple components 440 may be bonded with adjacent portions of a single component 405). For example, a system 400 may include the component 440-a, the component 405-a, the component 440-b, and the component 405-b, or a system may include the component 440-a and the component 440-b both bonded with the component 405-a. In some such examples, the molding material 420 may be formed around the molding material 430, the molding material 310, and the molding material 425 associated with the component 440-b and the component 405-b (e.g., along one or more sidewall surfaces of the respective molding materials).

In some examples, forming the molding materials 420 over the component 405 may protect the dies of the components 405 from damage during handling and manufacture. For example, the molding materials 420 may protect the sidewalls of the dies and the circuitry included in the dies, which may increase a yield of systems 400 and reduce electronic waste. Moreover, by separating and validating components 405 prior to bonding operations, systems 400 may be fabricated with a reduced rejection probability, which may further improve manufacturing yield of systems 400. For example, each component 405 may satisfy an evaluation operation prior to bonding, which may improve reliability of the system 400. Accordingly, by applying the techniques of the fabrication operations described herein, systems 400 may be manufactured with increased yield, improved performance, and reduced cost, among other benefits.

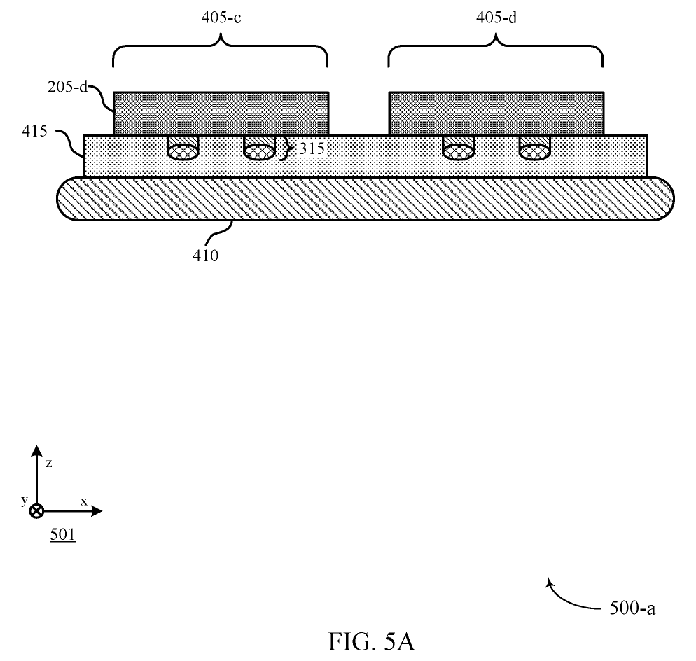

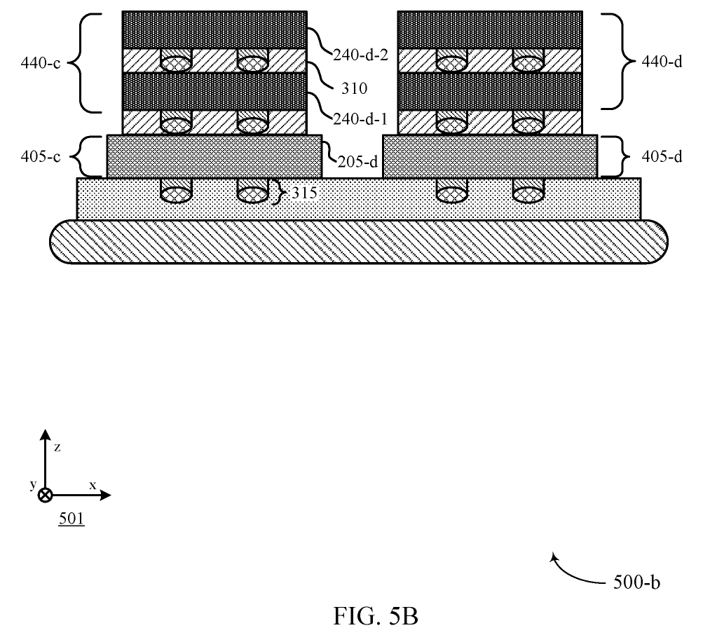

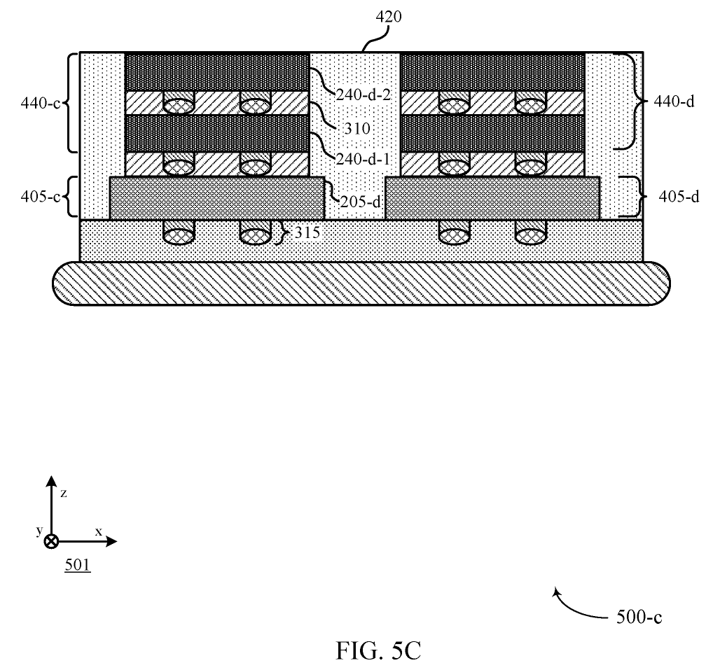

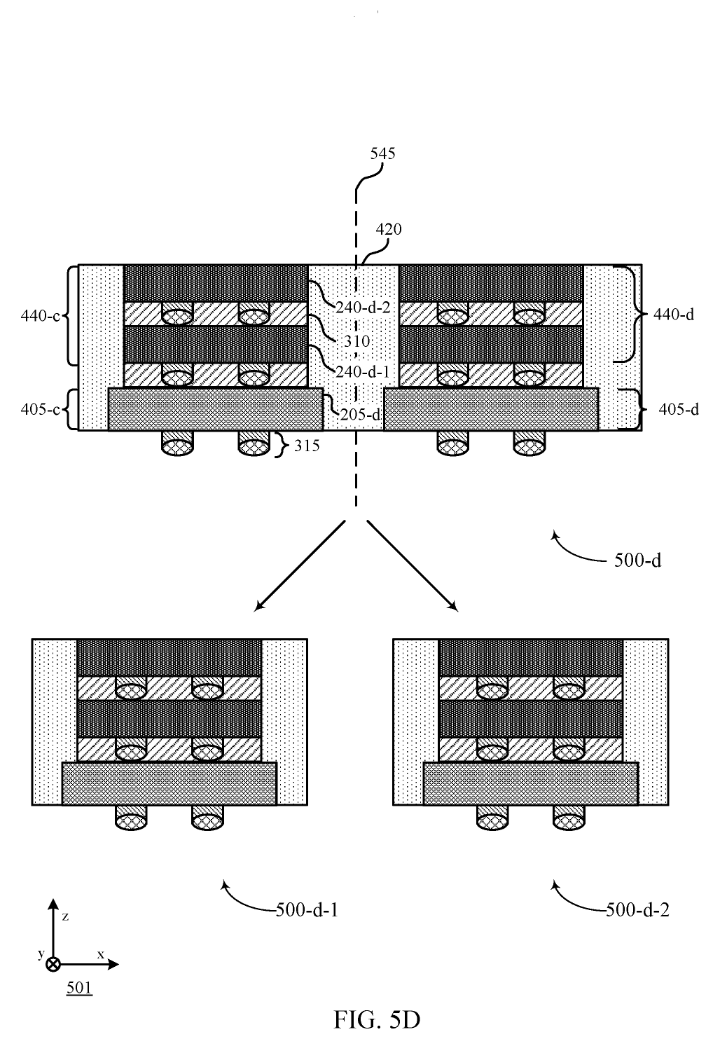

FIGS. 5A through 5D illustrate examples of operations that support edge protection for stacked semiconductor systems in accordance with examples as disclosed herein. Operations are illustrated with reference to a system 500 (e.g., a semiconductor system, a semiconductor stack, a semiconductor device, a semiconductor subcomponent), which may be an example of or include an electronic device (e.g., a system 100, a memory system 110, a host system 105, a system 200), or a portion thereof. For example, FIGS. 5A through 5D may illustrate aspects of a second sequence of operations that support manufacturing a system 100 or a portion thereof, a system 200 or a portion thereof, or some other device. Operations described with reference to FIGS. 5A through 5D may be performed in addition, or in alterative to the operations described with reference to FIGS. 4A through 4D. For example, one or more or more operations described as being performed with reference to FIGS. 4A through 4D may be performed (e.g., added) in any combination with the operations of FIGS. 5A through 5D, and vice-versa.

Each of FIGS. 5A through 5D may illustrate aspects of the system 500 after different subsets of the fabrication operations for forming the system 500 (e.g., illustrated as a system 500‑a after a first set of one or more fabrication operations, as a system 500‑b after a second set of one or more fabrication operations, and so on). Each view of FIGS. 5A through 5D may be described with reference to an x-direction, a y-direction, and a z-direction of a coordinate system 501. For example, aspects of the system 500 may be illustrated in accordance with a cut plane (e.g., along an xz-plane) to show embedded features of the system 500. Although, FIGS. 5A through 5D illustrate examples quantities of various features and example dimensionality, the techniques described herein may be applicable for various configurations of such aspects, including greater quantities than shown, fewer quantities than shown, and different dimensionality than shown.

Operations illustrated in and described with reference to FIGS. 5A through 5D may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the system 500. In some examples, operations performed by such a manufacturing system may be supported by a process controller or its components as described herein (e.g., including instructions stored in a non-transitory computer-readable medium that are executable by a processing system to cause the manufacturing system to perform the operations).

In some examples, portions of the system 500 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, some other conductive material, or any combination thereof.

FIG. 5A shows an example of a cross-sectional view of a system 500-a after a first set of one or more fabrication operations. For example, the first operations may include bonding components 405 (e.g., semiconductor components, components 405-c and 405-d) with a carrier 410. The first operations may also include or follow determining that each of the components 405 satisfies one or more evaluation operations. In some examples, bonding each of the components 405 with the carrier 410 may be based on determining that the component 405 satisfies one or more evaluation operations. In some examples, the bond between the components 405 and the carrier 410 may be based on the material 415, and contacts 315 may be embedded in (e.g., extend into) the material 415.

FIG. 5B shows an example of a cross-sectional view of a system 500-b after a second set of one or more fabrication operations. For example, the second operations may include bonding a respective component 440 (e.g., a component 440-c and a component 440-d) with each of the components 405. In some examples, each component 440 may include a respective set of one or more dies (e.g., dies 240-d) associated with respective first circuitry, and the respective first circuitry may be coupled with respective second circuitry of each component 405 based on the bonding. For example, the second operations may include a bonding of a front side of a respective die 240-d of the component 440 with a back side of a respective die 205-d of the component 405. In some examples, the second operations may include bonding a front side of a die 240-d-2 with a back side of each of the die 240-d-1 (e.g., dies 240-d of the component 440 may be sequentially stacked). In some examples, a bonding of one or more dies 240-d may occur before or after bonding of at least one die 240-d to the component 405 (e.g., to the die 205-d). In some examples, the second operations may include forming a molding material 310 between each respective die 240-d (e.g., after bonding the respective dies), or between a component 440 and a component 405, or both.

FIG. 5C shows an example of a cross-sectional view of a system 500-c after a third set of one or more fabrication operations. For example, the third operations may include forming (e.g., after bonding the components 440 with the components 405) a molding material 420 around (e.g., in an xy-plane) each component 440 along one or more sidewall surfaces (e.g., surfaces in xz-planes, surfaces in yz-planes) of each component 440 and around each component 405 along one or more sidewall surfaces of each component 405. Accordingly, the molding material 420 may protect the sidewalls of the components 440 and the components 405, which may improve fabrication yield of systems 500.

FIG. 5D shows an example of a cross-sectional view of a system 500-d after a fourth set of one or more fabrication operations. For example, the fourth operations may include exposing, based on separating the components 405 from the carrier 410 after bonding the components 440 with the components 405, contacts 315 at a surface (e.g., a front side) of each component 405 opposite from a surface (e.g., a back side) of the each component 405 bonded with the respective component 440. In some examples, the contacts 315 may be coupled with respective circuitry of the components 405. In some examples, the fourth operations may include separating one or more bonded components 440 and components 405 from other components. For example, the fourth operations may include separating a system 500-d-1 (e.g., including the component 440-c and the component 405-c) from the system 500-d-2 (e.g., including the component 440-d and the component 405-d) based on a separation (e.g., along a boundary 545, along a yz-plane) through the molding material 420. Alternatively, the system 500 may not be separated into a system 500-d-1 and a system 500-d-2.

Thus, a system 500 (e.g., a system 500-d-1, a system 500-d-2) may be fabricated to include one or more components 440, each of which may include one or more semiconductor dies (e.g., dies 240) associated with first circuitry. The system 500 may include one or more components 405 bonded with the component(s) 440 at a surface (e.g., a bonding surface) of the component 405. In some examples, the component(s) 405 may include one or more semiconductor dies (e.g., dies 205-d) associated with second circuitry, and the second circuitry may be electrically coupled with the first circuitry via one or more conductive paths between the component(s) 405 and the component(s) 440. The system 500 may include a molding material 420 around the component(s) 440 along one or more sidewall surfaces of the component(s) 440. The molding material 420 may also be around the component(s) 405 along one or more sidewall surfaces of the component(s) 405. In some examples, one or more sidewall surfaces of the molding material 420 (e.g., of the molding materials 420 of the system 500-d-1 or the system 500-d-2) may be indicative of a separation (e.g., based on a disfiguration, or indication of melting, grinding, cutting, or other separation methods) from one or more other portions of the molding material 420.

In some examples, forming the molding materials 420 over the component(s) 405 (e.g., and the component(s) 440) may protect dies of the components from damage during handling and manufacture. For example, the molding materials 420 may protect the sidewalls of the dies of at least the component(s) 405 and the circuitry therein, which may increase a yield of systems 500 and reduce electronic waste. Moreover, by separating and validating the components 405 prior to bonding operations, systems 500 may be fabricated with a reduced rejection probability, which may further improve manufacture yield of systems 500. For example, each die 205-d may satisfy an evaluation operation prior to bonding, which may improve reliability of the system 500. Accordingly, by applying the techniques of the fabrication operations described herein, systems 500 may be manufactured with increased yield, improved performance, and reduced cost, among other benefits.

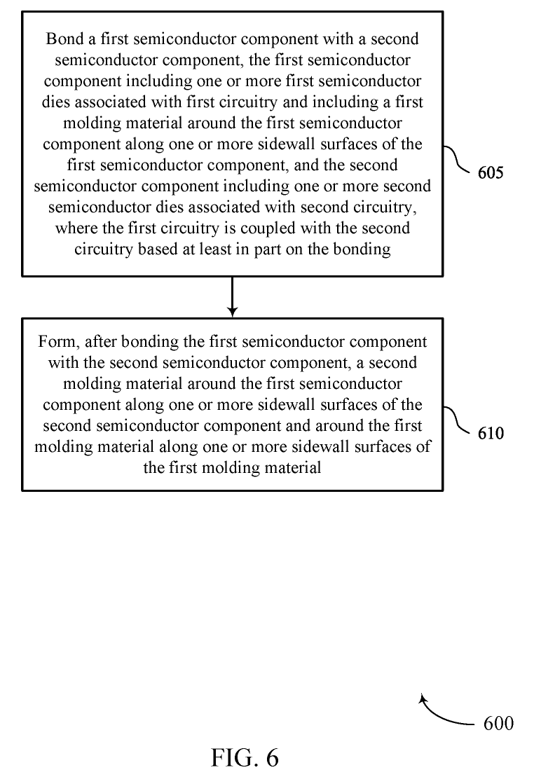

FIG. 6 shows a flowchart illustrating a method 600 that supports edge protection for stacked semiconductor systems in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include bonding a first semiconductor component (e.g., a component 340, a component 440) with a second semiconductor component (e.g., a component 305, a component 405), the first semiconductor component including one or more first semiconductor dies associated with first circuitry and including a first molding material around the first semiconductor component along one or more sidewall surfaces of the first semiconductor component, and the second semiconductor component including one or more second semiconductor dies associated with second circuitry, where the first circuitry is coupled with the second circuitry based at least in part on the bonding.

At 610, the method may include forming, after bonding the first semiconductor component with the second semiconductor component, a second molding material around the first semiconductor component along one or more sidewall surfaces of the second semiconductor component and around the first molding material along one or more sidewall surfaces of the first molding material.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a first semiconductor component with a second semiconductor component, the first semiconductor component including one or more first semiconductor dies associated with first circuitry and including a first molding material around the first semiconductor component along one or more sidewall surfaces of the first semiconductor component, and the second semiconductor component including one or more second semiconductor dies associated with second circuitry, where the first circuitry is coupled with the second circuitry based at least in part on the bonding and forming, after bonding the first semiconductor component with the second semiconductor component, a second molding material around the first semiconductor component along one or more sidewall surfaces of the second semiconductor component and around the first molding material along one or more sidewall surfaces of the first molding material.

Aspect 2: The method or apparatus of aspect 1, where the one or more first semiconductor dies include plurality of first semiconductor dies bonded in a stack.

Aspect 3: The method, apparatus, or non-transitory computer-readable medium of aspect 2, where the first semiconductor component includes a third molding material between one or more pairs of the plurality of first semiconductor dies, the third molding material in contact with the first molding material.

Aspect 4: The method or apparatus of any of aspects 1 through 3, further including operations, features, circuitry, logic, means, or instructions, or any combination thereof for forming, before forming the second molding material, a third molding material between the first semiconductor component and the second semiconductor component, the third molding material in contact with a surface of the first semiconductor component, a surface of the second semiconductor component, the first molding material, the second molding material formed in contact with the third molding material.

Aspect 5: The method or apparatus of any of aspects 1 through 4, where bonding the first semiconductor component with the second semiconductor component includes operations, features, circuitry, logic, means, or instructions, or any combination thereof for bonding a front side of a first semiconductor die of the one or more first semiconductor dies with a back side of a second semiconductor die of the one or more second semiconductor dies.

Aspect 6: The method or apparatus of any of aspects 1 through 5, further including operations, features, circuitry, logic, means, or instructions, or any combination thereof for bonding, before bonding the first semiconductor component with the second semiconductor component, the second semiconductor component with a carrier.

Aspect 7: The method or apparatus of aspect 6, further including operations, features, circuitry, logic, means, or instructions, or any combination thereof for determining that the second semiconductor component satisfies one or more evaluation operations, where bonding the second semiconductor component with the carrier is based at least in part on the determining.

Aspect 8: The method or apparatus of any of aspects 6 through 7, further including operations, features, circuitry, logic, means, or instructions, or any combination thereof for exposing, based at least in part on separating the second semiconductor component from the carrier after bonding the first semiconductor component with the second semiconductor component, one or more conductive contacts at surface of the second semiconductor component opposite from a surface of the second semiconductor component bonded with the first semiconductor component, the one or more conductive contacts coupled with the second circuitry.

Aspect 9: The method or apparatus of any of aspects 1 through 8, further including operations, features, circuitry, logic, means, or instructions, or any combination thereof for bonding a third semiconductor component with the second semiconductor component, the third semiconductor component including one or more third semiconductor dies associated with third circuitry and including a second portion of the first molding material around the third semiconductor component along one or more sidewall surfaces of the third semiconductor component, where the third circuitry is coupled with the second circuitry based at least in part on the bonding and where the second molding material is formed, after bonding the third semiconductor component with the second semiconductor component, around the second portion of the first molding material along one or more sidewall surfaces of the second portion of the first molding material.

Aspect 10: The method or apparatus of any of aspects 1 through 9, further including operations, features, circuitry, logic, means, or instructions, or any combination thereof for bonding a third semiconductor component with a fourth semiconductor component, the third semiconductor component including one or more third semiconductor dies associated with third circuitry and including a second portion of the first molding material around the third semiconductor component along one or more sidewall surfaces of the third semiconductor component, and the fourth semiconductor component including one or more fourth semiconductor dies associated with fourth circuitry, where the third circuitry is coupled with the fourth circuitry based at least in part on the bonding and where the second molding material is formed, after bonding the third semiconductor component with the fourth semiconductor component, around the fourth semiconductor component along one or more sidewall surfaces of the fourth semiconductor component and around the second portion of the first molding material along one or more sidewall surfaces of the second portion of the first molding material.

Aspect 11: The method or apparatus of aspect 10, further including operations, features, circuitry, logic, means, or instructions, or any combination thereof for separating the bonded first and second semiconductor components from the bonded third and fourth semiconductor components based at least in part on a separation through the second molding material.

Aspect 12: The method or apparatus of any of aspects 1 through 11, where each of the one or more first semiconductor dies includes a respective set of one or more memory arrays and the second circuitry includes interface circuitry operable to access the respective sets of one or more memory arrays.

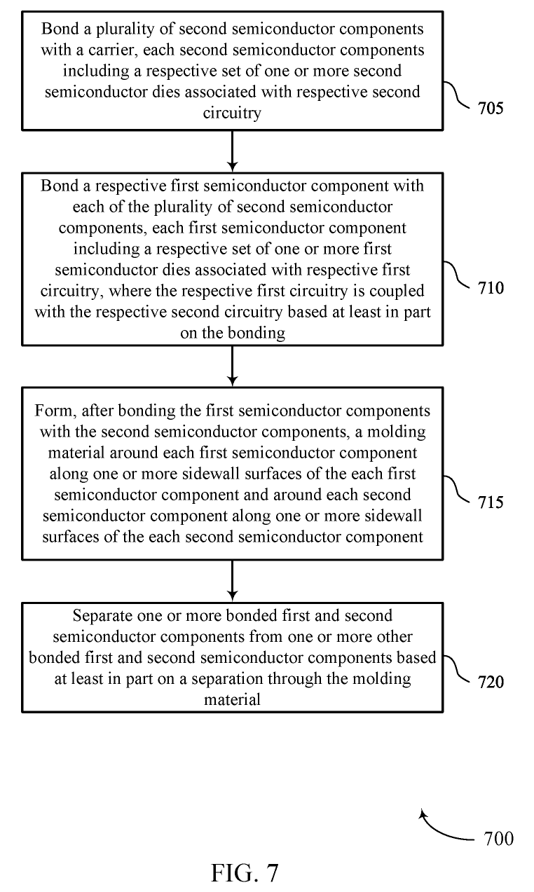

FIG. 7 shows a flowchart illustrating a method 700 that supports edge protection for stacked semiconductor systems in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include bonding a plurality of second semiconductor components (e.g., components 305, components 405) with a carrier, each second semiconductor component including a respective set of one or more second semiconductor dies associated with respective second circuitry.

At 710, the method may include bonding a respective first semiconductor component (e.g., component 340, a component 440) with each of the plurality of second semiconductor components, each first semiconductor component including a respective set of one or more first semiconductor dies associated with respective first circuitry, where the respective first circuitry is coupled with the respective second circuitry based at least in part on the bonding.

At 715, the method may include forming, after bonding the first semiconductor components with the second semiconductor components, a molding material around each first semiconductor component along one or more sidewall surfaces of the each first semiconductor component and around each second semiconductor component along one or more sidewall surfaces of the each second semiconductor component.

At 720, the method may include separating one or more bonded first and second semiconductor components from one or more other bonded first and second semiconductor components based at least in part on a separation through the molding material.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 13: A method or apparatus including operations, features, circuitry, logic, means, or instructions, or any combination thereof for bonding a plurality of second semiconductor components with a carrier, each second semiconductor component including a respective set of one or more second semiconductor dies associated with respective second circuitry; bonding a respective first semiconductor component with each of the plurality of second semiconductor components, each first semiconductor component including a respective set of one or more first semiconductor dies associated with respective first circuitry, where the respective first circuitry is coupled with the respective second circuitry based at least in part on the bonding; forming, after bonding the first semiconductor components with the second semiconductor components, a molding material around each first semiconductor component along one or more sidewall surfaces of the each first semiconductor component and around each second semiconductor component along one or more sidewall surfaces of the each second semiconductor component; and separating one or more bonded first and second semiconductor components from one or more other bonded first and second semiconductor components based at least in part on a separation through the molding material.

Aspect 14: The method or apparatus of aspect 13, where bonding the respective first semiconductor component with each of the plurality of second semiconductor components includes operations, features, circuitry, logic, means, or instructions, or any combination thereof for bonding a front side of a respective first semiconductor die of the respective first semiconductor component with a back side of a respective second semiconductor die of the second semiconductor component.

Aspect 15: The method or apparatus of aspect 14, further including operations, features, circuitry, logic, means, or instructions, or any combination thereof for bonding, after bonding the front side of the respective first semiconductor die with the back side of the respective second semiconductor die, a front side of a respective third semiconductor die with a back side of each of the respective first semiconductor dies.

Aspect 16: The method or apparatus of any of aspects 14 through 15, further including operations, features, circuitry, logic, means, or instructions, or any combination thereof for forming, prior to forming the molding material, a second molding material between each respective first semiconductor dies and each respective third semiconductor die, the molding material formed in contact with the second molding material.

Aspect 17: The method or apparatus of any of aspects 13 through 16, further including operations, features, circuitry, logic, means, or instructions, or any combination thereof for determining that each of the plurality of second semiconductor components satisfy one or more evaluation operations, where bonding each of the plurality of second semiconductor components with the carrier is based at least in part on the determining.

Aspect 18: The method or apparatus of any of aspects 13 through 17, further including operations, features, circuitry, logic, means, or instructions, or any combination thereof for exposing, based at least in part on separating the second semiconductor components from the carrier after bonding the first semiconductor components with the second semiconductor components, one or more conductive contacts at surface of each second semiconductor component opposite from a surface of the each second semiconductor component bonded with the respective first semiconductor component, the one or more conductive contacts coupled with the respective second circuitry.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 19: A semiconductor system, including: a first semiconductor component (e.g., a component 340, a component 440) including one or more first semiconductor dies associated with first circuitry; a second semiconductor component (e.g., a component 305, a component 405) bonded with the first semiconductor component and including one or more second semiconductor dies associated with second circuitry, the second circuitry being electrically coupled with the first circuitry via one or more conductive paths between the second semiconductor component and the first semiconductor component; a first molding material around the first semiconductor component along one or more sidewall surfaces of the first semiconductor component; and a second molding material around the second semiconductor component along one or more sidewall surfaces of the second semiconductor component and around the first molding material along one or more sidewall surfaces of the first molding material.

Aspect 20: The semiconductor system of aspect 19, where the one or more first semiconductor dies includes plurality of first semiconductor dies bonded in a stack.

Aspect 21: The semiconductor system of aspect 20, further including: a third molding material between one or more pairs of the plurality of first semiconductor dies, the third molding material in contact with the first molding material.

Aspect 22: The semiconductor system of any of aspects 20 through 21, where each of the plurality of first semiconductor dies includes a respective set of one or more memory arrays of a plurality of memory arrays and the second circuitry includes interface circuitry operable to access the plurality of memory arrays.

Aspect 23: The semiconductor system of any of aspects 19 through 22, further including: a fourth molding material between the first semiconductor component and the second semiconductor component, the fourth molding material in contact with a surface of the first semiconductor component, a surface of the second semiconductor component, the first molding material, and the second molding material.

Aspect 24: The semiconductor system of any of aspects 19 through 23, further including: one or more conductive contacts at surface of the second semiconductor component opposite from a surface of the second semiconductor component bonded with the first semiconductor component, the one or more conductive contacts coupled with the second circuitry.

Aspect 25: The semiconductor system of any of aspects 19 through 24, where: the one or more sidewall surfaces of the first semiconductor component extend from a bonding surface of the first semiconductor component; and the one or more sidewall surfaces of the second semiconductor component extend from a bonding surface of the second semiconductor component.

Aspect 26: The semiconductor system of any of aspects 19 through 25, where one or more sidewall surfaces of the second molding material are indicative of a separation from one or more other portions of the second molding material.

Aspect 27: The semiconductor system of any of aspects 19 through 26, further including: a third semiconductor component including one or more third semiconductor dies associated with third circuitry, the second circuitry being electrically coupled with the third circuitry via one or more second conductive paths between the second semiconductor component and the third semiconductor component; and a third molding material around the third semiconductor component along one or more sidewall surfaces of the third semiconductor component, the second molding material being around the third molding material along one or more sidewall surfaces of the third molding material.

An apparatus is described. The following provides an overview of aspects of the apparatus as described herein:

Aspect 28: A semiconductor system formed by a process including: bonding a first semiconductor component with a second semiconductor component, the first semiconductor component including one or more first semiconductor dies associated with first circuitry and a first molding material around the first semiconductor component along one or more sidewall surfaces of the first semiconductor component, and the second semiconductor component including one or more second semiconductor dies associated with second circuitry, where the first circuitry is coupled with the second circuitry based at least in part on the bonding; and forming, after bonding the first semiconductor component with the second semiconductor component, a second molding material around the first semiconductor component along one or more sidewall surfaces of the second semiconductor component and around the first molding material along one or more sidewall surfaces of the first molding material.

An apparatus is described. The following provides an overview of aspects of the apparatus as described herein:

Aspect 29: A semiconductor system formed by a process including: bonding a plurality of second semiconductor components with a carrier, each second semiconductor component including a respective set of one or more second semiconductor dies associated with respective second circuitry; bonding a respective first semiconductor component with each of the plurality of second semiconductor components, each first semiconductor component including a respective set of one or more first semiconductor dies associated with respective first circuitry, where the respective first circuitry is coupled with the respective second circuitry based at least in part on the bonding; forming, after bonding the first semiconductor components with the second semiconductor components, a molding material around each first semiconductor component along one or more sidewall surfaces of the each first semiconductor component and around each second semiconductor component along one or more sidewall surfaces of the each second semiconductor component; and separating one or more bonded first and second semiconductor components from one or more other bonded first and second semiconductor components based at least in part on a separation through the molding material.

An apparatus is described. The following provides an overview of aspects of the apparatus as described herein:

Aspect 30: A semiconductor system, including: a first semiconductor component (e.g., a component 340, a component 440) including one or more first semiconductor dies associated with first circuitry; a second semiconductor component (e.g., a component 305, a component 405) bonded with the first semiconductor component at a surface of the second semiconductor component, the second semiconductor component including one or more second semiconductor dies associated with second circuitry, the second circuitry being electrically coupled with the first circuitry via one or more conductive paths between the second semiconductor component and the first semiconductor component; and a molding material around the first semiconductor component along one or more sidewall surfaces of the first semiconductor component and around the second semiconductor component along one or more sidewall surfaces of the second semiconductor component, where one or more sidewall surfaces of the molding material are indicative of a separation from one or more other portions of the molding material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Some examples and operations described herein may be described with reference to sides of a semiconductor component. For example, a side of a semiconductor component may be referred to as a “back side” or “back,” or a “front side” or “front.” A front side of a semiconductor component may refer to a side (e.g., relative to a semiconductor substrate, such as a crystalline silicon substrate) that includes components such as transistors and capacitors. The front side may also include an electrically conductive metallization structure with chip contact areas. The front side may include front end of line (FEOL), middle of line (MOL), and back end of line (BEOL) layers. The front side may face up during at least some manufacturing processes and may include operative circuitry for the device’s operation (e.g., a side from which a substrate is doped to form transistor and other circuitry). In some examples, a back side of a semiconductor component may refer to a side (e.g., relative to the semiconductor substrate) that is opposite from at least some of the functional circuitry of the semiconductor component. A back side may be used for various supporting functions that complement the front side. For example, a back side of a semiconductor component may be bonded with a carrier while operations are performed on a front side, such as doping and metallization operations.

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor component comprising one or more first semiconductor dies associated with first circuitry;
a second semiconductor component bonded with the first semiconductor component and comprising one or more second semiconductor dies associated with second circuitry, the second circuitry being electrically coupled with the first circuitry via one or more conductive paths between the second semiconductor component and the first semiconductor component;
a first molding material around the first semiconductor component along one or more sidewall surfaces of the first semiconductor component; and
a second molding material around the second semiconductor component along one or more sidewall surfaces of the second semiconductor component and around the first molding material along one or more sidewall surfaces of the first molding material.

2. The semiconductor system of claim 1, wherein the one or more first semiconductor dies comprises plurality of first semiconductor dies bonded in a stack.

3. The semiconductor system of claim 2, further comprising:
a third molding material between one or more pairs of the plurality of first semiconductor dies, the third molding material in contact with the first molding material.

4. The semiconductor system of claim 2, wherein each of the plurality of first semiconductor dies comprises a respective set of one or more memory arrays of a plurality of memory arrays and the second circuitry comprises interface circuitry operable to access the plurality of memory arrays.

5. The semiconductor system of claim 1, further comprising:
a fourth molding material between the first semiconductor component and the second semiconductor component, the fourth molding material in contact with a surface of the first semiconductor component, a surface of the second semiconductor component, the first molding material, and the second molding material.

6. The semiconductor system of claim 1, further comprising:
one or more conductive contacts at surface of the second semiconductor component opposite from a surface of the second semiconductor component bonded with the first semiconductor component, the one or more conductive contacts coupled with the second circuitry.

7. The semiconductor system of claim 1, wherein:
the one or more sidewall surfaces of the first semiconductor component extend from a bonding surface of the first semiconductor component; and
the one or more sidewall surfaces of the second semiconductor component extend from a bonding surface of the second semiconductor component.

8. The semiconductor system of claim 1, wherein one or more sidewall surfaces of the second molding material are indicative of a separation from one or more other portions of the second molding material.

9. The semiconductor system of claim 1, further comprising:
a third semiconductor component comprising one or more third semiconductor dies associated with third circuitry, the second circuitry being electrically coupled with the third circuitry via one or more second conductive paths between the second semiconductor component and the third semiconductor component; and
a third molding material around the third semiconductor component along one or more sidewall surfaces of the third semiconductor component, the second molding material being around the third molding material along one or more sidewall surfaces of the third molding material.

10. A method of semiconductor system formation, comprising:
bonding a first semiconductor component with a second semiconductor component, the first semiconductor component comprising one or more first semiconductor dies associated with first circuitry and comprising a first molding material around the first semiconductor component along one or more sidewall surfaces of the first semiconductor component, and the second semiconductor component comprising one or more second semiconductor dies associated with second circuitry, wherein the first circuitry is coupled with the second circuitry based at least in part on the bonding; and
forming, after bonding the first semiconductor component with the second semiconductor component, a second molding material around the first semiconductor component along one or more sidewall surfaces of the second semiconductor component and around the first molding material along one or more sidewall surfaces of the first molding material.

11. The method of claim 10, wherein the one or more first semiconductor dies comprise plurality of first semiconductor dies bonded in a stack.

12. The method of claim 11, wherein the first semiconductor component comprises a third molding material between one or more pairs of the plurality of first semiconductor dies, the third molding material in contact with the first molding material.

13. The method of claim 10, further comprising:
forming, before forming the second molding material, a third molding material between the first semiconductor component and the second semiconductor component, the third molding material in contact with a surface of the first semiconductor component, a surface of the second semiconductor component, the first molding material, the second molding material formed in contact with the third molding material.

14. The method of claim 10, wherein bonding the first semiconductor component with the second semiconductor component comprises:
bonding a front side of a first semiconductor die of the one or more first semiconductor dies with a back side of a second semiconductor die of the one or more second semiconductor dies.

15. The method of claim 10, further comprising:
bonding, before bonding the first semiconductor component with the second semiconductor component, the second semiconductor component with a carrier.

16. The method of claim 15, further comprising:
determining that the second semiconductor component satisfies one or more evaluation operations, wherein bonding the second semiconductor component with the carrier is based at least in part on the determining.

17. The method of claim 15, further comprising:
exposing, based at least in part on separating the second semiconductor component from the carrier after bonding the first semiconductor component with the second semiconductor component, one or more conductive contacts at surface of the second semiconductor component opposite from a surface of the second semiconductor component bonded with the first semiconductor component, the one or more conductive contacts coupled with the second circuitry.

18. The method of claim 10, further comprising:
bonding a third semiconductor component with the second semiconductor component, the third semiconductor component comprising one or more third semiconductor dies associated with third circuitry and comprising a second portion of the first molding material around the third semiconductor component along one or more sidewall surfaces of the third semiconductor component, wherein the third circuitry is coupled with the second circuitry based at least in part on the bonding,
wherein the second molding material is formed, after bonding the third semiconductor component with the second semiconductor component, around the second portion of the first molding material along one or more sidewall surfaces of the second portion of the first molding material.

19. The method of claim 10, further comprising:
bonding a third semiconductor component with a fourth semiconductor component, the third semiconductor component comprising one or more third semiconductor dies associated with third circuitry and comprising a second portion of the first molding material around the third semiconductor component along one or more sidewall surfaces of the third semiconductor component, and the fourth semiconductor component comprising one or more fourth semiconductor dies associated with fourth circuitry, wherein the third circuitry is coupled with the fourth circuitry based at least in part on the bonding,
wherein the second molding material is formed, after bonding the third semiconductor component with the fourth semiconductor component, around the fourth semiconductor component along one or more sidewall surfaces of the fourth semiconductor component and around the second portion of the first molding material along one or more sidewall surfaces of the second portion of the first molding material.

20. The method of claim 19, further comprising:
separating the bonded first and second semiconductor components from the bonded third and fourth semiconductor components based at least in part on a separation through the second molding material.

21. The method of claim 10, wherein each of the one or more first semiconductor dies comprises a respective set of one or more memory arrays and the second circuitry comprises interface circuitry operable to access the respective sets of one or more memory arrays.

22. A semiconductor system formed by a process comprising:
bonding a first semiconductor component with a second semiconductor component, the first semiconductor component comprising one or more first semiconductor dies associated with first circuitry and a first molding material around the first semiconductor component along one or more sidewall surfaces of the first semiconductor component, and the second semiconductor component comprising one or more second semiconductor dies associated with second circuitry, wherein the first circuitry is coupled with the second circuitry based at least in part on the bonding; and
forming, after bonding the first semiconductor component with the second semiconductor component, a second molding material around the first semiconductor component along one or more sidewall surfaces of the second semiconductor component and around the first molding material along one or more sidewall surfaces of the first molding material.

23. A method of semiconductor system formation, comprising:
bonding a plurality of second semiconductor components with a carrier, each second semiconductor component comprising a respective set of one or more second semiconductor dies associated with respective second circuitry;
bonding a respective first semiconductor component with each of the plurality of second semiconductor components, each first semiconductor component comprising a respective set of one or more first semiconductor dies associated with respective first circuitry, wherein the respective first circuitry is coupled with the respective second circuitry based at least in part on the bonding;
forming, after bonding the first semiconductor components with the second semiconductor components, a molding material around each first semiconductor component along one or more sidewall surfaces of the each first semiconductor component and around each second semiconductor component along one or more sidewall surfaces of the each second semiconductor component; and
separating one or more bonded first and second semiconductor components from one or more other bonded first and second semiconductor components based at least in part on a separation through the molding material.

24. The method of claim 23, wherein bonding the respective first semiconductor component with each of the plurality of second semiconductor components comprises:
bonding a front side of a respective first semiconductor die of the respective first semiconductor component with a back side of a respective second semiconductor die of the second semiconductor component.

25. The method of claim 24, further comprising:
bonding, after bonding the front side of the respective first semiconductor die with the back side of the respective second semiconductor die, a front side of a respective third semiconductor die with a back side of each of the respective first semiconductor dies.

26. The method of claim 24, further comprising:
forming, prior to forming the molding material, a second molding material between each respective first semiconductor dies and each respective third semiconductor die, the molding material formed in contact with the second molding material.

27. The method of claim 23, further comprising:
determining that each of the plurality of second semiconductor components satisfy one or more evaluation operations, wherein bonding each of the plurality of second semiconductor components with the carrier is based at least in part on the determining.

28. The method of claim 23, further comprising:
exposing, based at least in part on separating the second semiconductor components from the carrier after bonding the first semiconductor components with the second semiconductor components, one or more conductive contacts at surface of each second semiconductor component opposite from a surface of the each second semiconductor component bonded with the respective first semiconductor component, the one or more conductive contacts coupled with the respective second circuitry.

29. A semiconductor system, comprising:
a first semiconductor component comprising one or more first semiconductor dies associated with first circuitry;
a second semiconductor component bonded with the first semiconductor component at a surface of the second semiconductor component, the second semiconductor component comprising one or more second semiconductor dies associated with second circuitry, the second circuitry being electrically coupled with the first circuitry via one or more conductive paths between the second semiconductor component and the first semiconductor component; and
a molding material around the first semiconductor component along one or more sidewall surfaces of the first semiconductor component and around the second semiconductor component along one or more sidewall surfaces of the second semiconductor component, wherein one or more sidewall surfaces of the molding material are indicative of a separation from one or more other portions of the molding material.
